(19) United States
(12) Patent Application Publication
(10) Pub. No.: US 2007/0152315 A1
(43) Pub. Date: Jul. 5, 2007

(54) Multi-die package and method for fabricating same

(75) Inventors: Kyu-Sub Kwak, Seoul (KR); Kyung-Wan Park, Suwon-si (KR); Seung-Woo Han, Seoul (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/521,038

(22) Filed: Sep. 14, 2006

(30) Foreign Application Priority Data
Jan. 3, 2006 (KR) 2006-567

(51) Int. Cl. H01L 23/02

(52) U.S. Cl. 257/686

(57) ABSTRACT

A multi-die package and a method of fabrication is discloses. The multi-die package includes a package substrate, a first semiconductor die bonded directly on the package substrate and connected electrically with the package substrate, and a second semiconductor die having a groove providing a receiving space, bonded directly on the package substrate so that the first semiconductor die is covered by the groove, and connected electrically with the package substrate.

### CLAIM OF PRIORITY

This application claims the benefit of the earlier filing date, pursuant to 35 USC 119, to that patent application entitled “Multi-Die Package,” filed in the Korean Intellectual Property Office on Jan. 3, 2006 and assigned Serial No. 2006-567, the contents of which are hereby incorporated by reference.

### BACKGROUND OF THE INVENTION

1. Field of the Invention

The present invention relates to a semiconductor package, and more particularly to a multi-die package in which a plurality of semiconductor dies are stacked.

2. Description of the Related Art

Semiconductor packaging technology provides for electrically and physically connecting semiconductor dies to a package substrate, and includes multi-die packaging technology, which is usually used to downsize the footprint of a semiconductor package. Here, each die may include a memory die, an image processor die, an audio processor die, or the like.

FIG. 1 illustrates a cross-sectional view of a conventional multi-die package. The multi-die package 100 includes a package substrate 110, and first to fourth semiconductor dies 120, 122, 124 and 140.

The first to third semiconductor dies 120, 122 and 124 are stacked on a top surface of the package substrate 110 in that order, and the first semiconductor die 120 is directly bonded on the top surface of the package substrate 110. A first insulation member 130 is interposed between the first and second semiconductor dies 120 and 122, and a second insulation member 132 is interposed between the second and third semiconductor dies 122 and 124. An edge of each of the semiconductor dies 120, 122 and 124 is bonded to the top surface of the package substrate 110 by wires 150, so that the semiconductor dies 120, 122 and 124 are electrically connected with the package substrate 110. Further, the first to third semiconductor dies 120, 122 and 124 are subjected to transfer molding using a first molding material 160.

The fourth semiconductor die 140 is directly bonded onto the bottom surface of the package substrate 110. The fourth semiconductor die 140 is provided thereon with a ball grid array (BGA) 145 for electrical connection, and through the BGA 145 physically and electrically connected to the package substrate 110. In other words, the fourth semiconductor die 140 is subjected to flip chip bonding on the package substrate 110. Further, the fourth semiconductor die 140 is under-filled with a second molding material 170.

However, because a region for bonding the fourth semiconductor die 140 should be secured on the bottom surface of the package substrate 110, restrictions are imposed on the number of input/output (I/O) pins of the package substrate 110, and the entire height of the multi-die package 100 increases in order to secure a desired stand-off height. Further, in order to mold the first to fourth semiconductor dies 120, 122, 124 and 140, the transfer molding process should be applied to the upside of the multi-die package 100, and the underfill process should be applied to the downside of the multi-die package 100. Hence, an overall production process is complicated, and thus production yield is lowered.

### SUMMARY OF THE INVENTION

Accordingly, the present invention has been made to solve the above-mentioned problems occurring in the prior art and provides additional advantages, by providing a multi-package die capable of improving a density of integration, simplifying a production process, and improving tolerance of an alignment or size error.

According to an aspect of the present invention, there is provided a multi-die package that includes a package substrate; a first semiconductor die bonded directly onto the package substrate and connected electrically with the package substrate; and a second semiconductor die having a groove, channel, furrow or well, providing a receiving space therein, so that the first semiconductor die is covered by the second semiconductor die, bonded directly on the package substrate and connected electrically to the package substrate.

### BRIEF DESCRIPTION OF THE DRAWINGS

The above features and advantages of the present invention will be more apparent from the following detailed description taken in conjunction with the accompanying drawings, in which:

FIG. 1 illustrates a cross-sectional view of conventional multi-die package;

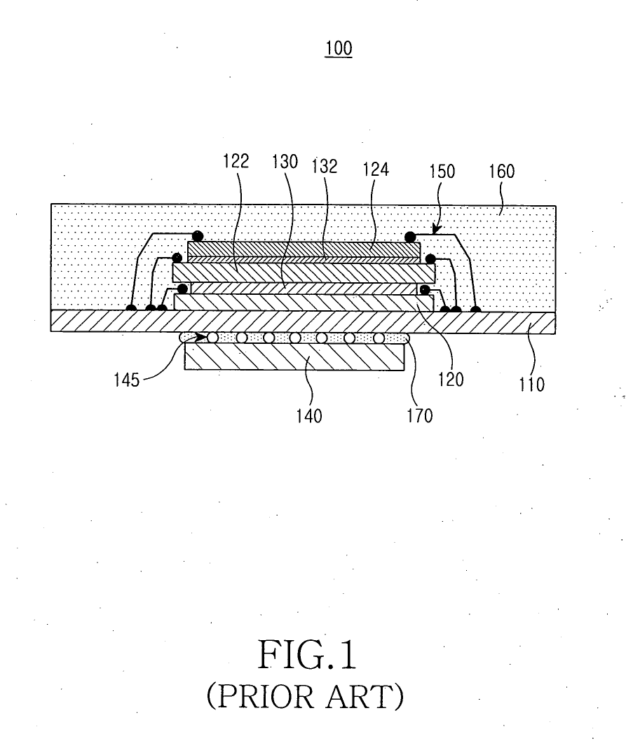

FIG. 2 is a cross-sectional view illustrating a multi-die package according to an exemplary embodiment of the present invention;

FIG. 3 is a top plan view illustrating the multi-die package shown in FIG. 2;

FIG. 4 is a perspective view illustrating the second semiconductor die shown in FIG. 2; and

FIG. 5 is a perspective view illustrating a semiconductor die according to a second embodiment of the present invention.

### DETAILED DESCRIPTION OF THE INVENTION

Hereinafter, embodiments of the present invention will be described with reference to the accompanying drawings. For the purposes of clarity and simplicity, a detailed description of known functions and configurations incorporated herein will be omitted when it may make the subject matter of the present invention unclear.

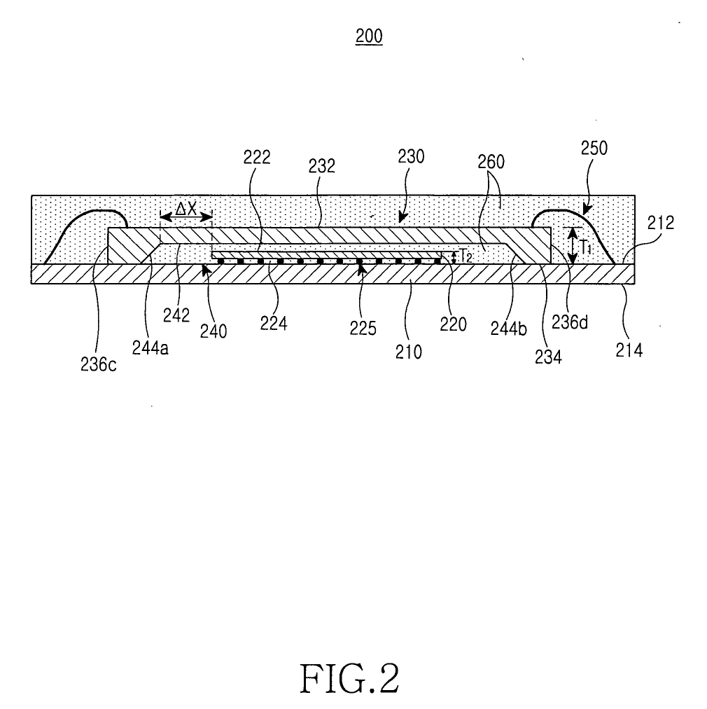

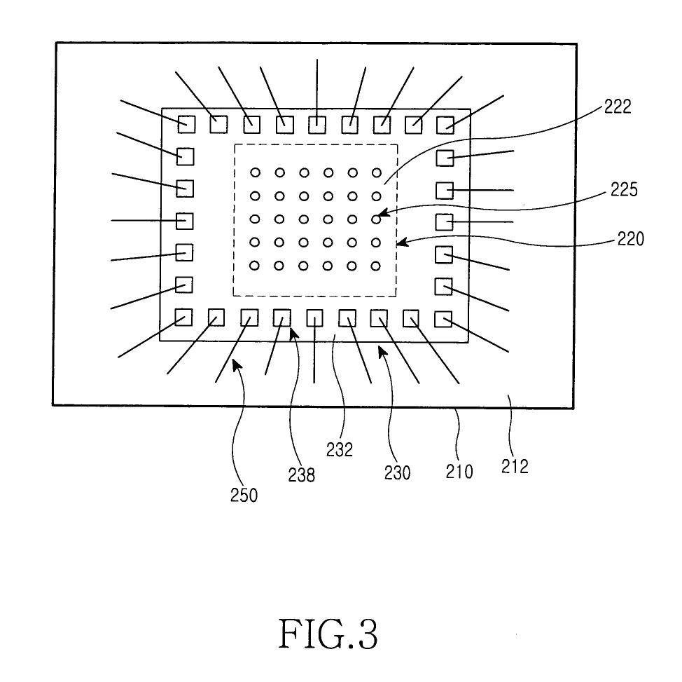

FIG. 2 is a cross-sectional view illustrating a multi-die package according to an exemplary embodiment of the present invention, and FIG. 3 is a top plan view illustrating multi-die package shown in FIG. 2. The multi-die package 200 includes a package substrate 210, and first and second semiconductor dies 220 and 230.

The package substrate 210 has the shape of a substantially quadrangular plate, and can be provided with a solder ball array for electrical connection with a substrate on a bottom surface 214 thereof. At this time, the package substrate 210 has top surface 212 and bottom surface 214 located opposite to each other.

The first semiconductor die 220 has the shape of substantially quadrangular plate, and is bonded directly on the top surface 212 of the package substrate 210. The first semiconductor die 220 has top and bottom surfaces 222 and 224, respectively, located opposite to each other. The first semiconductor die 220 is provided with a ball grid array (BGA) 225 on the bottom surface 224 for electrical and physical connection to the package substrate 210. The first semiconductor die 220 may be selected from circuits such as a static random access memory (SRAM), a dynamic RAM (DRAM), a flash memory, or more complex integrated circuits, and may have the shape of a chip scale package (CSP), a stacked CSP, or the like.

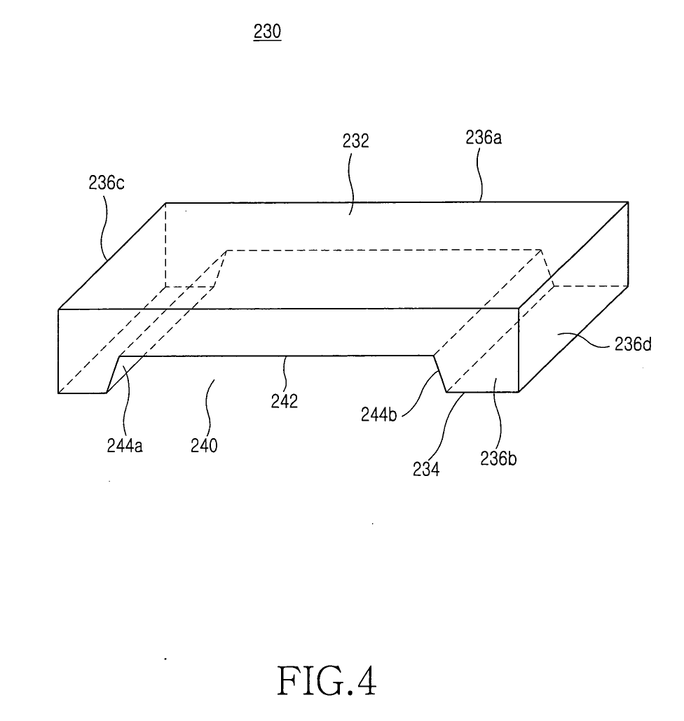

FIG. 4 is a perspective view illustrating a second semiconductor die 230 in accordance with the principles of the invention. The second semiconductor die 230 has the shape of a quadrangular plate, and is provided with a groove or channel 240 on a bottom surface 234 thereof. The second semiconductor die 230 has top and bottom surfaces 232 and 234, respectively, and first to fourth outer lateral surfaces 236a to 236d. The groove 240 extends from the first outer lateral surface 236a to the second outer lateral surfaces 236b of the second semiconductor die 230. The first and second outer lateral surfaces 236a and 236b are located opposite to each other. In order to form the groove 240, the second semiconductor die 230 has openings within first and second outer lateral surfaces 236a and 236b, a quadrangular inner base surface 242 parallel to the top surface 232, and first and second inner lateral surfaces 244a and 244b extending from the opposite sides of the inner base surface 242 to the opposite sides of the bottom surface 234 at a substantially slant angle of 45°. Although, a slant angle of 45° is shown, it would be recognized that the angle may be varied to conform to the geometry of enclosed first die (not shown).

The second semiconductor die 230 is directly bonded onto the top surface 212 of the package substrate 210 so that the first semiconductor die 220 is covered or encapsulated by the groove 240. The groove 240 has the shape of a tunnel, which is opened at both ends and, preferably, has a trapezoidal cross section. By performing transfer molding on the first semiconductor die 220 with a molding material 260, an empty space of the groove 240, which is composed of the space between the bottom surface 224 of the first semiconductor die 220 and the top surface 212 of the package substrate 210, is completely filled by the molding material 260. This transfer molding process can be performed by injecting the molding material 260 through the opened end of one side of the groove 240, and discharging the molding material 260, which is left after filling the inner space of the groove 240, through the opened end of the other side of the groove 240. An epoxy mold compound (EMC) can be used as the molding material 260.

The second semiconductor die 230 includes a plurality of bonding pads 238 for wire connection on an edge of the top surface 232 thereof. The second semiconductor die 230 is electrically connected to the package substrate 210 by wires 250 connecting the bonding pads 238 and the top surface 212 of the package substrate 210. Thereby, the second semiconductor die 230 is wire-bonded with the package substrate 210 using pads 238 shown in FIG. 3. The second semiconductor die 230 may include an image processor, an audio processor, or other similar complex integrated circuits. Each of the wires 250 (see FIG. 3) can be made of silver, gold, or similar electrically conductive material.

As the second semiconductor die 230 is transfer-molded by the molding material 260, the wires 250, the outer surfaces 232, and 236a to 236d of the second semiconductor die 230, and the exposed top surface 212 of the package substrate 210 are completely covered by the molding material 260.

The first and second semiconductor dies 220 and 230 can be simultaneously transfer-molded by a single process. More specifically, because the first semiconductor die 220 has the first and second outer lateral surfaces 236a and 236b, the first and second semiconductor dies 220 and 230 are bonded on the top surface 212 of the package substrate 210, and in this state, the first and second semiconductor dies 220 and 230 can be simultaneously transfer-molded.

When a size of the groove 240 within the second semiconductor die 230 is significantly larger than that of the first semiconductor die 220, it is possible to improve tolerance of the size and alignment errors of the first semiconductor die 220. At this time, the size of the semiconductor die refers to a size as seen in the top plan view. For example, a thickness T2 of the first semiconductor die 220 can be set to 250 μm, a thickness T1 of the second semiconductor die 230 can be set to approximately 450 μm, and an interval ΔX between one side of the inner base surface 242 of the second semiconductor die 230 and one end of the first semiconductor die 220 to 2.5 mm. Therefore, the first and second semiconductor dies 220 and 230 between which the end interval of 2.5 mm exists can be stacked, and the size or alignment error of the first semiconductor die 220 can be allowed up to 2.5 mm.

In another aspect of the present invention, a micro-electro-mechanical system (MEMS) can be used. Typically, the MEMS is a structure in which it is surrounded by an air layer without molding.

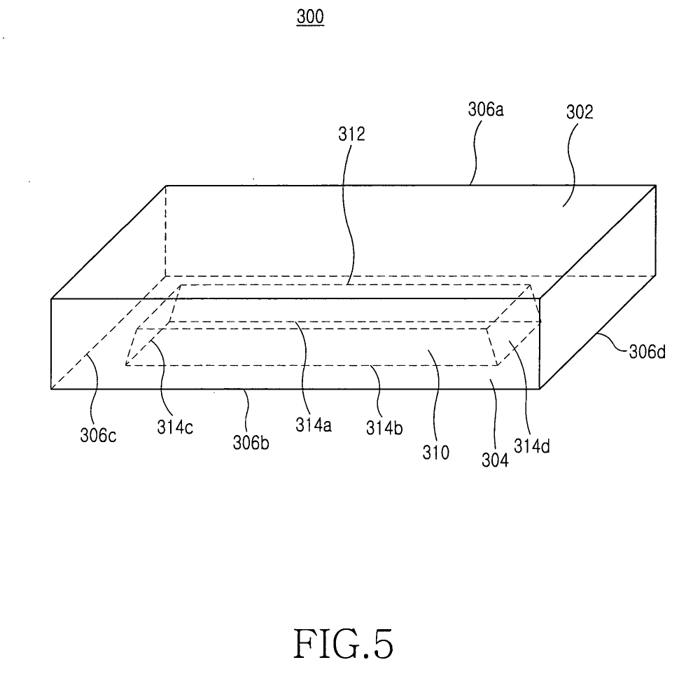

FIG. 5 is a perspective view illustrating an exemplary semiconductor die according to a second embodiment of the present invention. The second semiconductor die 300 has the shape of a quadrangular plate, and is provided with a groove on a lower side thereof. The second semiconductor die 300 has a top surface 302, a bottom surface 304, and first to fourth outer lateral surfaces 306a to 306d. The groove 310 is represented as a well structure in which either is completely contained (as shown) or only one end thereof being opened (not shown). In order to form the groove 310, the second semiconductor die 300 has a quadrangular inner base surface 312 parallel to the top surface 302, and first and fourth inner lateral surfaces 314a to 314d extending from the inner base surface 312 to the bottom surface 304 at a slant angle of substantially 45°.

The second semiconductor die 300 can replace the second semiconductor die 230 illustrated in FIG. 2. In this case, the inside of the groove 310 of the second semiconductor die 300 except the first semiconductor die 220 contained therein is maintained as an empty space.

As described above, the multi-die package according to the present invention is constructed to mount the first semiconductor die in the groove of the second semiconductor die, to increase the density of integration. Further, the multi-die package according to the present invention can mold the plurality of semiconductor dies through the single process, so that its production process is simple. Also, the multi-die package according to the present invention is constructed to mount the first semiconductor die in the groove of the second semiconductor die, so that it is tolerant of the alignment or size of the first semiconductor die. In addition, the multi-die package according to the present invention is constructed to mount the first semiconductor die in the groove of the second semiconductor die, so that it can be applied to the MEMS requiring a structure in which it is surrounded by an air layer without molding.

Although the invention has been described with regard to a first and second semiconductor die, it would recognized that the principles of the present invention may be applied to multiple semiconductor dies without changing the scope of the invention and is contemplated herein. Furthermore, while the present invention has been described with regard to wire bounding the second semiconductor die, with would recognized that the second semiconductor die may contain a BGA for electrically and physically connecting the second semiconductor die to the substrate.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A multi-die package comprising:
a package substrate;
a first semiconductor die bonded directly on the package substrate and connected electrically with the package substrate; and
a second semiconductor die bonded directly onto the package substrate and connected electrically with the package substrate, said second semiconductor die having a groove therein providing a receiving space, so that the first semiconductor die is covered by the groove.

2. The multi-die package according to claim 1, wherein the first semiconductor die is subjected to flip chip bonding with respect to the package substrate.

3. The multi-die package according to claim 1, wherein the second semiconductor die is subjected to wire bonding with respect to the package substrate.

4. The multi-die package according to claim 1, wherein the first and second semiconductor dies are together subjected to transfer molding by a molding material.

5. The multi-die package according to claim 1, wherein the groove has an inside thereof except the first semiconductor die is maintained as an empty space.

6. The multi-die package according to claim 1, wherein the groove extends to a first opening through a first edge of the second semiconductor die.

7. The multi-die package according to claim 7, wherein the groove extends to a second opening through a second edge of the second semiconductor die, the first and second edges being substantially parallel and opposite each other.

8. The multi-die package according to claim 1, wherein the groove is sized to accommodate a known measure of misalignment in the placement of the first semiconductor die.

9. A method for fabricating a multi-die package, the method comprising the steps of:
flip-chip mounting a first semiconductor die to a substrate; and
attaching a second semiconductor die to the substrate, the first semiconductor die being contained within a groove of the second semiconductor die.

10. The method according to claim 9, further comprising the step of:
injecting a molding compound through an opening in at least one edge of the second semiconductor die.

11. The method according to claim 9, wherein the step of attaching the second semiconductor die comprises the step of:
wire-bonding the second semi-conductor to the substrate.

12. The method according to claim 9, wherein the step of attaching the second semiconductor die comprises the step of:
flip-chip mounting the second semiconductor die to the substrate.

13. The method according to claim 9, wherein the groove is sized to accommodate a known measure of misalignment in the placement of the first semiconductor die.
